(19) United States
(12) Patent Application Publication
(10) Pub. No.: US 2023/0197506 A1
(43) Pub. Date: Jun. 22, 2023

(54) DECOUPLED INTERCONNECTS

(71) Applicant: International Business Machines Corporation, Armonk, NY (US)

(72) Inventors: Saumya Sharma, Easton, CT (US); Chih-Chao Yang, Glenmont, NY (US); Tianji Zhou, Albany, NY (US); Ashim Dutta, Clifton Park, NY (US)

(21) Appl. No.: 17/552,814

(22) Filed: Dec. 16, 2021

(51) Int. Cl. H01L 21/768; H01L 23/522; H01L 23/532

(52) U.S. Cl. CPC H01L 21/76831; H01L 21/76897; H01L 21/76885; H01L 21/76843; H01L 21/76877; H01L 23/5226; H01L 23/53209

(57) ABSTRACT

Embodiments of the present invention are directed to subtractive processing methods and resulting structures for semiconductor devices having decoupled interconnects. In a non-limiting embodiment of the invention, a first conductive line is formed in a dielectric layer. A conductive pillar is formed over the first conductive line and a liner is formed in a trench adjacent to the first conductive line. A portion of the liner extends over the conductive pillar. A lower metal line and a top via are subtractively formed on the liner in the trench.

### BACKGROUND

The present invention generally relates to fabrication methods and resulting structures for semiconductor devices, and more specifically, to subtractive processing methods and resulting structures for semiconductor devices having decoupled interconnects.

The fabrication of very large scale integrated (VLSI) or ultra large scale integrated (VLSI) circuits requires the manufacture of sophisticated interconnect structures including metallic wiring that connects individual devices in a semiconductor chip to one another. Typically, the wiring interconnect network consists of two types of features that serve as electrical conductors, namely, line features that traverse a distance across the chip, and conductive via features that connect lines in different levels. The conducting metal lines and conductive vias are made of conductive material, such as aluminum or copper, and are electrically insulated by interlayer dielectrics (ILD). In a multilayered interconnect structure, the layers in which lines are formed are called metallization layers and are referred to as “M” layers (e.g., M1 layer, M2 layer, etc.). The layers in which vias are formed are called “V” layers to denote the location of conductive vias placed between adjacent M layers (e.g., V1 is between the M1 and M2 layers).

To increase the number of circuits that can be provided on a chip, the transistor gate length and chip size have been manufactured at smaller sizes. As a consequence, the interconnect structures have also become smaller. As integrated circuit (IC) feature sizes continue to decrease, the aspect ratio, (i.e., the ratio of height/depth to width) of features such as conductive vias generally increases, complicating the manufacturing process. Fabricating intricate structures of conductive interconnect layers and high aspect ratio vias within increasingly smaller wafer footprints is one of the most process-intensive and cost-sensitive portions of semiconductor IC fabrication.

### SUMMARY

Embodiments of the invention are directed to a method for forming semiconductor devices having decoupled interconnects. A non-limiting example of the method includes forming a first conductive line in a dielectric layer. A conductive pillar is formed over the first conductive line and a liner is formed in a trench adjacent to the first conductive line. A portion of the liner extends over the conductive pillar. A lower metal line and a top via are subtractively formed on the liner in the trench.

Embodiments of the invention are directed to a semiconductor structure. A non-limiting example of the semiconductor structure includes a first conductive line in a dielectric layer and a conductive pillar over the first conductive line. A lower metal line is positioned adjacent to the first conductive line and a top via is positioned on the lower metal line. The top via and the lower metal line are monolithically formed from a common conductive material. A second conductive line is positioned on the top via and a third conductive line is positioned on the conductive pillar. A first dielectric separation distance between the lower metal line and the second conductive line is different than a second dielectric separation distance between the first conductive line and the third conductive line.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 depicts a cross-sectional view of a semiconductor structure after an initial set of processing operations according to one or more embodiments of the invention;

FIG. 2 depicts a cross-sectional view of the semiconductor structure after additional operations according to one or more embodiments of the invention;

FIG. 3 depicts a cross-sectional view of the semiconductor structure after additional operations according to one or more embodiments of the invention;

FIG. 4 depicts a cross-sectional view of the semiconductor structure after additional operations according to one or more embodiments of the invention;

FIG. 5 depicts a cross-sectional view of the semiconductor structure after additional operations according to one or more embodiments of the invention;

FIG. 6 depicts a cross-sectional view of the semiconductor structure after additional operations according to one or more embodiments of the invention;

FIG. 7 depicts a cross-sectional view of the semiconductor structure after additional operations according to one or more embodiments of the invention;

FIG. 8 depicts a cross-sectional view of the semiconductor structure after additional operations according to one or more embodiments of the invention;

FIG. 9 depicts a cross-sectional view of a semiconductor structure after a set of processing operations according to one or more embodiments of the invention;

FIG. 10 depicts a cross-sectional view of a semiconductor structure after a set of processing operations according to one or more embodiments of the invention;

FIG. 11 depicts a cross-sectional view of a semiconductor structure after a set of processing operations according to one or more embodiments of the invention; and

FIG. 12 depicts a flow diagram illustrating a method according to one or more embodiments of the invention.

The diagrams depicted herein are illustrative. There can be many variations to the diagram or the operations described therein without departing from the spirit of the invention. For instance, the actions can be performed in a differing order or actions can be added, deleted or modified.

In the accompanying figures and following detailed description of the described embodiments of the invention, the various elements illustrated in the figures are provided with two or three-digit reference numbers. With minor exceptions, the leftmost digit(s) of each reference number correspond to the figure in which its element is first illustrated.

### DETAILED DESCRIPTION

It is understood in advance that although example embodiments of the invention are described in connection with a particular transistor architecture, embodiments of the invention are not limited to the particular transistor architectures or materials described in this specification. Rather, embodiments of the present invention are capable of being implemented in conjunction with any other type of transistor architecture or materials now known or later developed.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the present invention, ICs are fabricated in a series of stages, including a front-end-of-line (FEOL) stage, a middle-of-line (MOL) stage, and a back-end-of-line (BEOL) stage. The process flows for fabricating modern ICs are often identified based on whether the process flows fall in the FEOL stage, the MOL stage, or the BEOL stage. Generally, the FEOL stage is where device elements (e.g., transistors, capacitors, resistors, etc.) are patterned in the semiconductor substrate/wafer. The FEOL stage processes include wafer preparation, isolation, gate patterning, and the formation of wells, source/drain (S/D) regions, extension junctions, silicide regions, and liners. The MOL stage typically includes process flows for forming the contacts (e.g., CA) and other structures that communicatively couple to active regions (e.g., gate, source, and drain) of the device element. For example, the silicidation of source/drain regions, as well as the deposition of metal contacts, can occur during the MOL stage to connect the elements patterned during the FEOL stage. Layers of interconnections (e.g., metallization layers) are formed above these logical and functional layers during the BEOL stage to complete the IC. Most ICs need more than one layer of wires to form all the necessary connections, and as many as 5-12 layers are added in the BEOL process. The various BEOL layers are interconnected by vias that couple from one layer to another. Insulating dielectric materials are used throughout the layers of an IC to perform a variety of functions, including stabilizing the IC structure and providing electrical isolation of the IC elements. For example, the metal interconnecting wires in the BEOL region of the IC are isolated by dielectric layers to prevent the wires from creating a short circuit with other metal layers.

The continued scaling of semiconductor devices has resulted in challenging fabrication requirements, especially when fabricating ever smaller metallization layers. Advanced BEOL processes incorporate phase-shifting, optical proximity correction, and other practices to satisfy these scaling demands, and can achieve a line-to-line pitch below 30 nm. As semiconductors continue to scale to smaller nodes, however, new challenges have surfaced. In particular, the simultaneous patterning of interconnects and devices in various areas of a die is becoming very challenging. Related challenges include the consumption of interconnect capping layers when ion beam etching, the creation of seams and voids in dielectric fill regions, dielectric and metal damage causing high RC delays, metal sidewall damage, and dielectric cap damage causing electromigration.

Turning now to an overview of aspects of the present invention, one or more embodiments of the invention address the above-described shortcomings by providing subtractive processing methods and resulting structures for semiconductor devices having decoupled interconnects. In accordance with embodiments of the invention, a new metallization fabrication technique is leveraged whereby one or more interconnect patterning steps (including, e.g., trench or/and via formation) is carried out separate from device patterning or other interconnect patterning steps. In other words, embodiments of the invention present a decoupled interconnect fabrication scheme. Advantageously, decoupled interconnect fabrication schemes ensure a run-path for interconnect manufacturability as we progress to smaller nodes.

In some embodiments of the invention, one or more interconnect fabrication processes are performed after nearby interconnect/device patterning steps are completed. In this manner, dielectric fill and metal trench or/and via structures are not impacted by the nearby patterning of those interconnects or devices. Interconnects that are formed later use a subtractive process to form their respective lower-level metal lines and top vias.

Forming interconnect structures according to one or more embodiments offers several technical benefits over conventional interconnect fabrication processes that are observable in the final device. For example, these techniques prevent damage to dielectrics while patterning interconnects, ensuring higher quality dielectrics and indirectly improving device reliability with low RC delay. Moreover, the present techniques can flexibly implement decoupled interconnects across several device sizes and design variants.

Decoupled interconnect fabrication also enables one or more interconnect patterns and materials to be built different than the others. For example, a given area of the die can provide an inter-layer dielectric separation distance (“a”) that is smaller or larger than the inter-layer dielectric separation distance (“b”) for other areas of the die (i.e., a In another example, metal lines in one area of the die can be built at different heights than in the other areas of the die at the same metallization level (i.e., inter-level height variations).

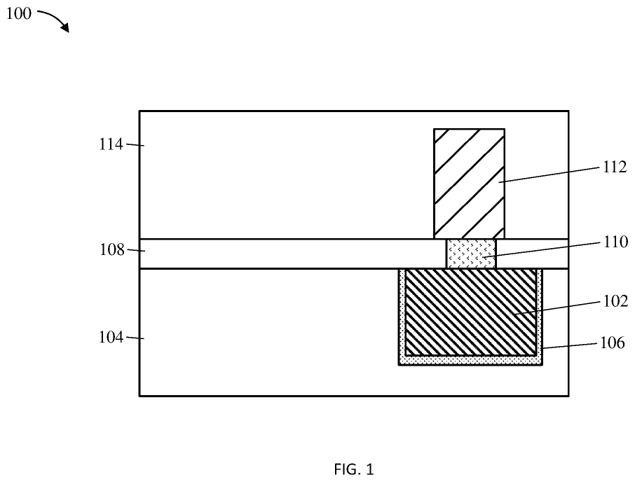

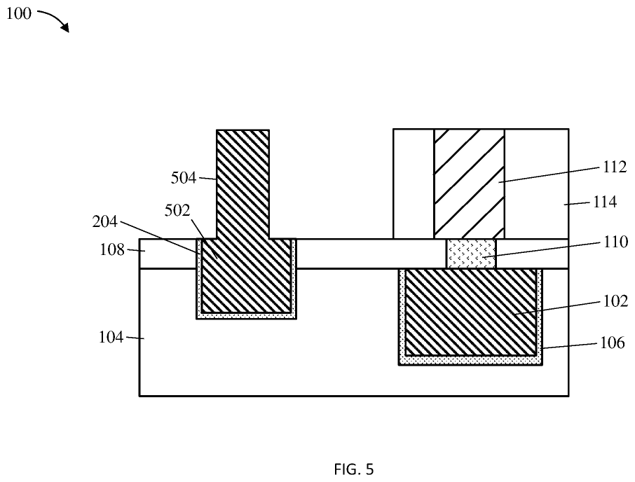

Turning now to a more detailed description of fabrication operations and resulting structures according to aspects of the invention, FIG. 1 depicts a cross-sectional view of a semiconductor structure 100 after an initial set of fabrication operations have been applied as part of a method of fabricating a final semiconductor device according to one or more embodiments of the invention. In some embodiments of the invention, a conductive line 102 is formed in a dielectric layer 104. In some embodiments of the invention, a liner 106 is positioned between the conductive line 102 and the dielectric layer 104. While not shown for ease of discussion, the conductive line 102 can be one of many lines in a metallization layer of the interconnect structure 100. Moreover, it is understood that the processes described herein, although described with reference to the conductive lines 102 and 503 (FIG. 5), can be used to create metal interconnects having stepped top vias in any metallization layer.

In some embodiments of the invention, the conductive line 102 includes a conductive material formed or deposited in a trench (not separately shown) in the dielectric layer 104 using known back-end-of-line (BEOL) processes. In some embodiments of the invention, the conductive line 102 is overfilled above a surface of the trench, forming overburdens that can be removed using, for example, a chemical-mechanical planarization (CMP) process. The conductive line 102 can be made of any suitable conducting material, such as, for example, metal (e.g., tungsten, titanium, tantalum, ruthenium, zirconium, cobalt, copper, aluminum, platinum), alloys thereof (such as AlCu, CuMn, CuTi, or the like), conducting metallic compound material (e.g., tantalum nitride, titanium nitride, tantalum carbide, titanium carbide, titanium aluminum carbide, tungsten silicide, tungsten nitride, cobalt silicide, nickel silicide), conductive carbon, or any suitable combination of these materials. In some embodiments of the invention, the conductive line 102 is a copper line (copper interconnect). The conductive line 102 can be formed or deposited using, for example, CVD, PECVD, PVD, sputtering, plating, chemical solution deposition, and electroless plating.

In some embodiments of the invention, the dielectric layer 104 is an interlayer dielectric. The dielectric layer 104 serves as an isolation structure for the lines and vias of the interconnect structure 100. The dielectric layer 104 can be made of any suitable dielectric material, such as, for example, low-k dielectrics (materials having a small dielectric constant relative to silicon dioxide, i.e., less than about 3.9), ultra-low-k dielectrics (materials having a dielectric constant less than 3.0), porous silicates, carbon doped oxides, silicon dioxides, silicon nitrides, silicon oxynitrides, silicon carbide, or other dielectric materials. Any known manner of forming the dielectric layer 104 can be utilized, such as, for example, CVD, PECVD, ALD, flowable CVD, spin-on dielectrics, or PVD.

The liner 106 can serve as a diffusion barrier, preventing copper (or other metal) in the conductive line 102 from diffusing into, or doping, the surrounding dielectric materials, which can degrade their properties. Silicon, for example, forms deep-level traps when doped with copper. An ideal barrier metal liner must limit copper diffusivity sufficiently to chemically isolate the copper conductor from the surrounding materials and should have a high electrical conductivity, for example, tantalum nitride and tantalum (TaN/Ta), titanium, titanium nitride, cobalt, ruthenium, and manganese. In some embodiments of the invention, the liner 106 is a multi-layer liner (e.g., a two-layer liner). In some embodiments of the invention, a first liner layer can act as a diffusion barrier and the second liner layer can act as a wetting layer that improves the gap-filling capabilities of subsequently deposited materials (i.e., the bulk conductor) while also improving electromigration. In some embodiments of the invention, the first liner layer includes TaN or Ta while the second liner layer includes Co or Ru.

In some embodiments of the invention, an insulating layer 108 is formed on the dielectric layer 104 and the conductive line 102. The insulating layer 108 can be made of any suitable dielectric material, such as, for example, silicon carbide, silicon nitride, hydrogenated silicon carbonitrides (SiC(N, H)), silicon oxide, and silicon oxynitrides (SiC(N, O, H)). Any known manner of forming the insulating layer 108 can be utilized, such as, for example, CVD, PECVD, ALD, flowable CVD, spin-on dielectrics, or PVD. In some embodiments of the invention, the insulating layer 108 is formed to a thickness of 5 nm to 200 nm, although other thicknesses are within the contemplated scope of the disclosure.

In some embodiments of the invention, a conductive plug 110 is formed in the insulating layer 108. In some embodiments of the invention, the conductive plug 110 is formed directly on a surface of the conductive line 102. In this manner the conductive plug 110 electrically couples the conductive line 102 to conductive elements above the insulating layer 108. In some embodiments of the invention, the conductive plug 110 is a metal vertical plug (or pedestal). In some embodiments of the invention, the conductive plug 110 is a via.

In some embodiments of the invention, a conductive pillar 112 is formed on the conductive plug 110. The conductive pillar 112 can be a horizontal line or vertical plug/via in the semiconductor structure 100. The conductive pillar 112 can be formed in a similar manner and from similar materials as the conductive line 102. In some embodiments of the invention, the conductive pillar 112 is made of a same conductive material as the conductive line 102. In some embodiments of the invention, the conductive pillar 112 is made of a different conductive material than the conductive line 102.

In some embodiments of the invention, a dielectric layer 114 is formed over the insulating layer 108 and the conductive pillar 112. In some embodiments of the invention, the dielectric layer 114 is an interlayer dielectric. The dielectric layer 114 can be formed in a similar manner and from similar materials as the dielectric layer 104.

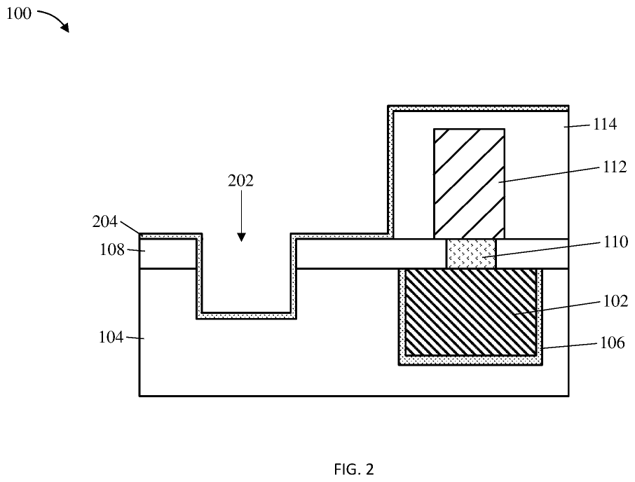

FIG. 2 depicts a cross-sectional view of the semiconductor structure 100 after additional operations have been applied as part of a method of fabricating a final semiconductor device according to one or more embodiments of the invention. In some embodiments of the invention, the dielectric layer 114 is patterned to expose a surface of the insulating layer 108. The dielectric layer 114 can be patterned using any suitable process, such as, for example, a wet etch, a dry etch, or a combination of sequential wet and/or dry etches. In some embodiments of the invention, a block mask (not shown) is formed over first portions of the dielectric layer 114 and second, exposed portions of the dielectric layer 114 are removed. In some embodiments of the invention, the exposed portion of the insulating layer 108 defines a logic area of the semiconductor structure 100.

As further shown in FIG. 2, in some embodiments of the invention, portions of the insulating layer 108 and the dielectric layer 104 are removed to form a trench 202. The trench 202 can be formed using any suitable patterning scheme, such as, for example, lithographic patterning (e.g., trilayer or quad-layer patterning stacks) followed by a removal process (e.g., an OPL etch and/or wet or dry etching).

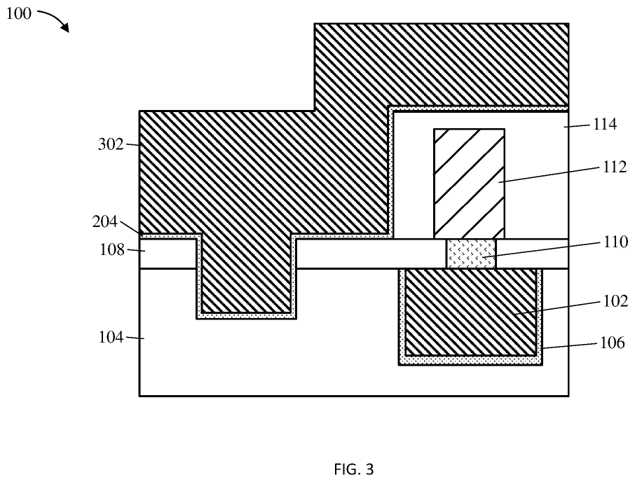

In some embodiments of the invention, a liner 204 is formed in the trench 202. The liner 204 serves two purposes. First, the liner 204 serves as a diffusion barrier for a subsequently formed conductive line (see, e.g., FIG. 5), in a similar manner as discussed previously with respect to the liner 106. Second, the liner 204 prevents damage to the dielectric layer 114 while the subsequently formed conductive line is processed (see, e.g., FIGS. 3-5). The liner 204 can be made of any suitable barrier material, such as, for example, TaN/Ta, titanium, titanium nitride, cobalt, ruthenium, and manganese. The liner 204 can be formed using any suitable process. In some embodiments of the invention, the liner 204 is conformally deposited over the semiconductor structure 100 (as shown).

FIG. 3 depicts a cross-sectional view of the semiconductor structure 100 after additional operations have been applied as part of a method of fabricating a final semiconductor device according to one or more embodiments of the invention. In some embodiments of the invention, a bulk conductive layer 302 is formed over the liner 204. The conductive layer 302 can be made of any suitable conducting material, such as, for example, metal (e.g., tungsten, titanium, tantalum, ruthenium, zirconium, cobalt, copper, aluminum, platinum), alloys thereof (such as AlCu, CuMn, CuTi, or the like), conducting metallic compound material (e.g., tantalum nitride, titanium nitride, tantalum carbide, titanium carbide, titanium aluminum carbide, tungsten silicide, tungsten nitride, cobalt silicide, nickel silicide), conductive carbon, or any suitable combination of these materials. In some embodiments of the invention, the conductive layer 302 includes copper. The conductive layer 302 can be formed or deposited using, for example, CVD, PECVD, PVD, ALD, sputtering, plating, chemical solution deposition, and electroless plating.

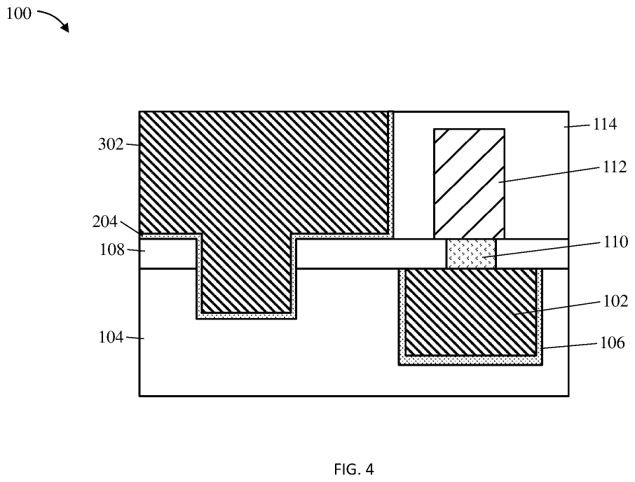

FIG. 4 depicts a cross-sectional view of the semiconductor structure 100 after additional operations have been applied as part of a method of fabricating a final semiconductor device according to one or more embodiments of the invention. In some embodiments of the invention, the conductive layer 302 is planarized (polished) using, for example, CMP. In some embodiments of the invention, the conductive layer 302 is polished until a surface of the dielectric layer 114 is exposed (as shown).

FIG. 5 depicts a cross-sectional view of the semiconductor structure 100 after additional operations have been applied as part of a method of fabricating a final semiconductor device according to one or more embodiments of the invention. In some embodiments of the invention, the conductive layer 302 is subtractively patterned to form a lower metal line 502 and a top via 504. The conductive layer 302 can be subtractively patterned using, for example, a wet etch, a dry etch, or a combination of sequential wet and/or dry etches. In some embodiments of the invention, the dielectric layer 114 is recessed and a surface of the conductive pillar 112 is exposed during the subtractive patterning process.

Advantageously, subtractive patterning allows the lower metal line 502 and the top via 504 to be monolithically formed from a common conductive material (e.g., the conductive layer 302). In this manner, the lower metal line 502 and the top via 504 collectively define a seamless interconnect structure with low internal resistance (i.e., an interconnect structure having no seams or intervening barrier layers). While formed from a common structure, the “lower metal line” 502 generally refers to the portion of the conductive layer 302 below a surface of the insulating layer 108. Conversely, the “top via” 502 generally refers to the portion of the conductive layer 302 above the surface of the insulating layer 108.

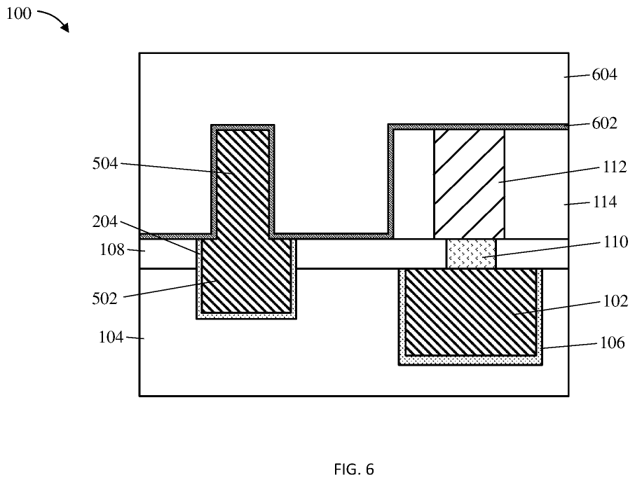

FIG. 6 depicts a cross-sectional view of the semiconductor structure 100 after additional operations have been applied as part of a method of fabricating a final semiconductor device according to one or more embodiments of the invention. In some embodiments of the invention, a capping layer 602 is formed over the semiconductor structure 100. In some embodiments of the invention, the capping layer 602 is conformally deposited over the semiconductor structure 100. In some embodiments of the invention, the capping layer 602 is formed to a thickness of 1 nm to 20 nm, although other thicknesses are within the contemplated scope of the disclosure. The capping layer 602 can be made of any suitable dielectric material, such as, for example, silicon carbide, silicon nitride, and hydrogenated silicon carbonitrides. Any known manner of forming the capping layer 602 can be utilized, such as, for example, CVD, PECVD, ALD, and PVD.

In some embodiments of the invention, a dielectric layer 604 is formed over the capping layer 602. In some embodiments of the invention, the dielectric layer 604 is an interlayer dielectric. The dielectric layer 604 can be formed in a similar manner and from similar materials as the dielectric layer 104.

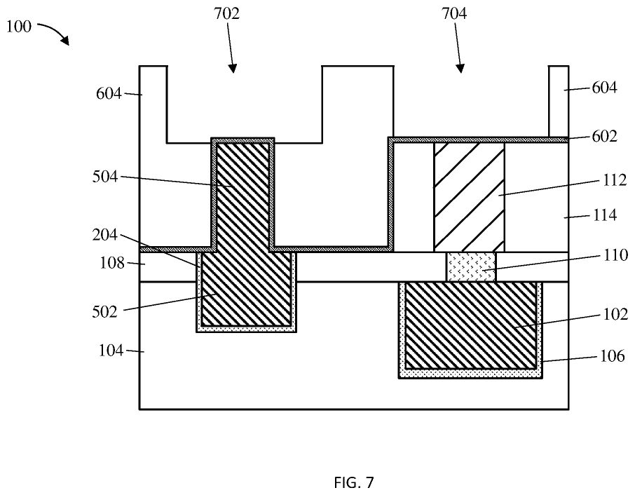

FIG. 7 depicts a cross-sectional view of the semiconductor structure 100 after additional operations have been applied as part of a method of fabricating a final semiconductor device according to one or more embodiments of the invention. In some embodiments of the invention, portions of the dielectric layer 604 are removed to form trenches 702, 704. The trenches 702, 704 can be formed using any suitable process, such as, for example, a wet etch, a dry etch, or a combination of sequential wet and/or dry etches. In some embodiments of the invention, the trench 702 exposes a portion of the capping layer 602 over the top via 504. In some embodiments of the invention, the trench 704 exposes a portion of the capping layer 602 over the conductive pillar 112.

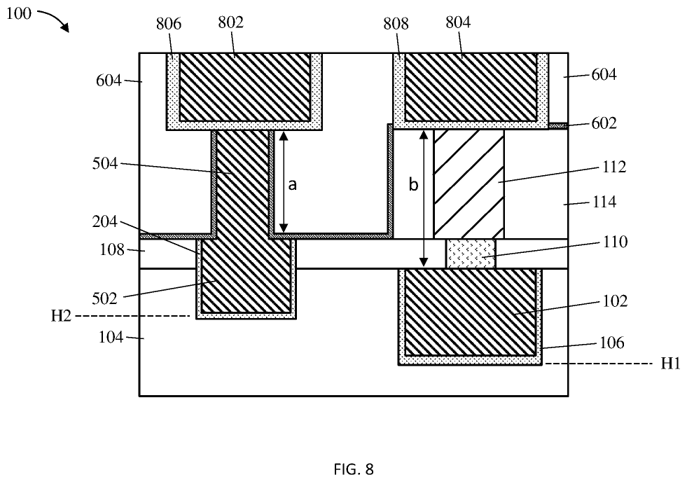

FIG. 8 depicts a cross-sectional view of the semiconductor structure 100 after additional operations have been applied as part of a method of fabricating a final semiconductor device according to one or more embodiments of the invention. In some embodiments of the invention, a first conductive line 802 is formed in the trench 702 and a second conductive line 804 is formed in the trench 704.

The conductive lines 802, 804 can be made of any suitable conducting material, such as, for example, metal (e.g., tungsten, titanium, tantalum, ruthenium, zirconium, cobalt, copper, aluminum, platinum), alloys thereof (such as AlCu, CuMn, CuTi, or the like), conducting metallic compound material (e.g., tantalum nitride, titanium nitride, tantalum carbide, titanium carbide, titanium aluminum carbide, tungsten silicide, tungsten nitride, cobalt silicide, nickel silicide), conductive carbon, or any suitable combination of these materials. In some embodiments of the invention, the conductive lines 802, 804 are made of the same conductive materials. In some embodiments of the invention, the conductive lines 802, 804 are made of different conductive materials. The conductive lines 802, 804 can be formed or deposited together or separately using, for example, CVD, PECVD, PVD, sputtering, plating, chemical solution deposition, and electroless plating. In some embodiments of the invention, a surface of the top via 504 and/or a surface of the conductive pillar 112 is exposed prior to forming the first conductive line 802 and/or the second conductive line 804 (as shown).

In some embodiments of the invention, a liner 806 is formed in the trench 702 prior to the conductive line 802. Similarly, in some embodiments of the invention, a liner 808 is formed in the trench 704 prior to the conductive line 804. The liners 806, 808 can serve as diffusion barriers for the conductive lines 802, 804, in a similar manner as discussed previously with respect to the liner 106. The liners 806, 808 can be made of any suitable barrier material, such as, for example, TaN/Ta, titanium, titanium nitride, cobalt, ruthenium, and manganese. The liners 806, 808 can be formed using any suitable process. In some embodiments of the invention, the liners 806, 808 are conformally deposited over the semiconductor structure 100 and a polishing process exposes a surface of the dielectric layer 604.

As further shown in FIG. 8, constructing the semiconductor structure 100 as discussed with respect to FIGS. 1-8 allows for an inter-layer dielectric separation distance (“a”) in a first region of the semiconductor structure 100 that is smaller than an inter-layer dielectric separation distance (“b”) for a second region of the semiconductor structure 100 (observe that a≠b). Moreover, the heights “H1” and “H2” (measured with respect to, e.g., the bottom surface of the dielectric layer 104) of the conductive line 102 and the lower metal line 502, respectively, are decoupled. In other words, the conductive line 102 is formed at a first height (e.g., H1) that is less than (lower than) a second height (e.g., H2) of the lower metal line 502. In other words, the process scheme discussed with respect to FIGS. 1-8 results in a decoupled interconnect structure.

It should be understood that the particular inter-layer dielectric separation distances a and b and the heights H1 and H2 shown in FIG. 8 are for ease of discussion only. Advantageously, each of the inter-layer dielectric separation distances a, b and the heights H1, H2 can be increased or decreased as desired for a given application. For example, the trench (not separately shown) into which the conductive line 102 is formed can be increased or decreased in depth with respect to the depth of the trench 202. Similarly, the depth of the trench 202 can be increased or decreased as desired. In another example, the height of the conductive pillar 112 can be increased or decreased as desired. Each of these techniques can be combined or used separately to achieve the desired conditions. In this manner, arbitrary differences in metal line heights can be built throughout the semiconductor structure 100.

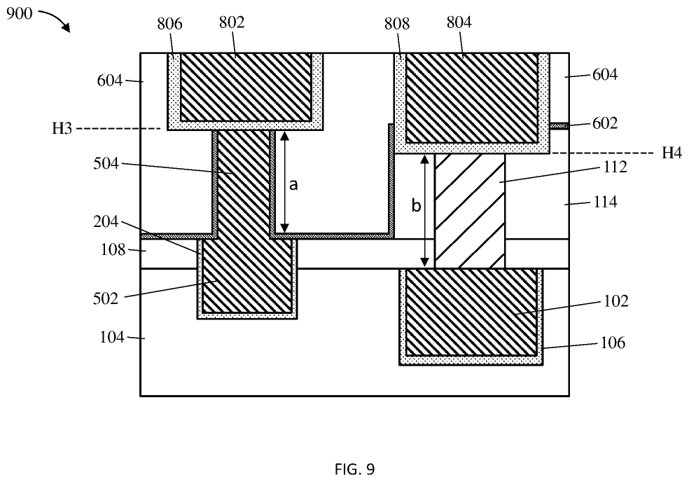

FIG. 9 depicts a cross-sectional view of a semiconductor structure 900 after a set of fabrication operations have been applied as part of a method of fabricating a final semiconductor device according to one or more embodiments of the invention. The semiconductor structure 900 depicts an alternative embodiment from the semiconductor structure 100 shown in FIGS. 1-8, where the conductive pillar 112 is formed directly on the conductive line 102. In other words, a structure without the conductive plug 110.

As shown in FIG. 9, forming the conductive pillar 112 directly on the conductive line 102 results in a decrease in the inter-layer dielectric separation distance (“b”). Moreover, the heights “H3” and “H4” of the first conductive line 802 and the second conductive line 804, respectively, have decoupled. In other words, the first conductive line 802 is formed at a first height (e.g., H3) that is greater than a second height (e.g., H4) of the second conductive line 804.

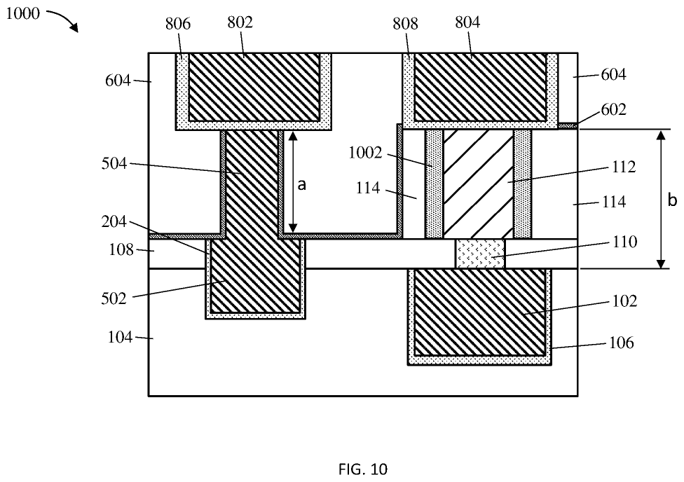

FIG. 10 depicts a cross-sectional view of a semiconductor structure 1000 after a set of fabrication operations have been applied as part of a method of fabricating a final semiconductor device according to one or more embodiments of the invention. The semiconductor structure 1000 depicts an alternative embodiment from the semiconductor structure 100 shown in FIGS. 1-8.

As shown in FIG. 10, in some embodiments of the invention, spacers 1002 are formed on sidewalls of the conductive pillar 112. The spacers 1002 can be made of any suitable dielectric material, such as, for example, silicon carbide, silicon nitride, hydrogenated silicon carbonitrides (SiC(N, H)), silicon oxide, and silicon oxynitrides (SiC(N, O, H)). Any known manner of forming the spacers 1002 can be utilized, such as, for example, CVD, PECVD, ALD, flowable CVD, spin-on dielectrics, or PVD. In some embodiments of the invention, the spacers 1002 are formed to a thickness of 1 nm to 20 nm, although other thicknesses are within the contemplated scope of the disclosure.

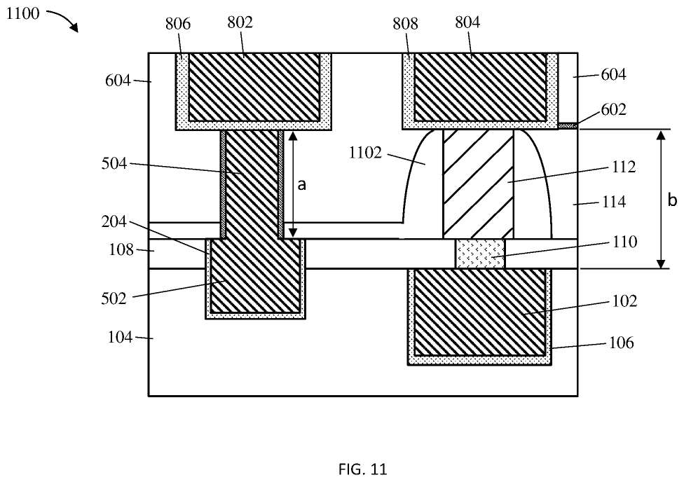

FIG. 11 depicts a cross-sectional view of a semiconductor structure 1100 after a set of fabrication operations have been applied as part of a method of fabricating a final semiconductor device according to one or more embodiments of the invention. The semiconductor structure 1100 depicts an alternative embodiment from the semiconductor structure 1000 shown in FIG. 10.

As shown in FIG. 11, in some embodiments of the invention, spacers 1102 are formed on sidewalls of the conductive pillar 112. The spacers 1102 can be made of any suitable dielectric material, such as, for example, silicon carbide, silicon nitride, hydrogenated silicon carbonitrides (SiC(N, H)), silicon oxide, and silicon oxynitrides (SiC(N, O, H)). Any known manner of forming the spacers 1102 can be utilized, such as, for example, CVD, PECVD, ALD, flowable CVD, spin-on dielectrics, or PVD. In some embodiments of the invention, the spacers 1102 are formed to a thickness of 20 nm to 200 nm, although other thicknesses are within the contemplated scope of the disclosure. In contrast to the spacers 1002 (FIG. 10), the spacers 1102 extend over a surface of the insulating layer 108, largely replacing portions of the capping layer 602. In some embodiments of the invention, portions of the capping layer 602 are removed prior to forming the spacers 1102 (as shown).

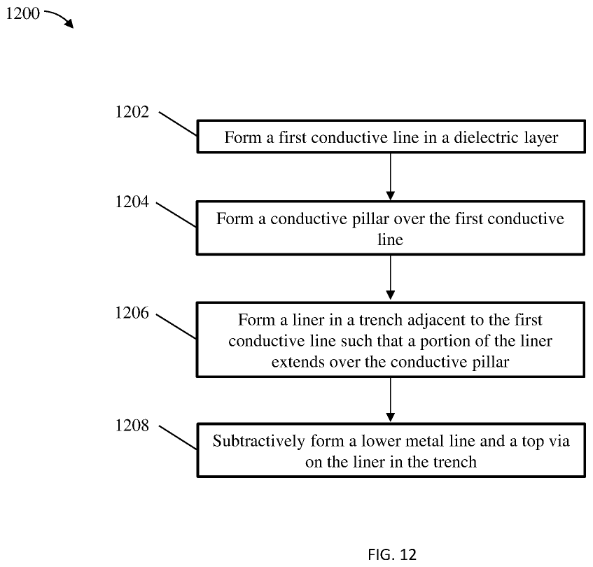

FIG. 12 depicts a flow diagram 1200 illustrating a method for subtractively forming decoupled interconnects according to one or more embodiments of the invention. As shown at block 1202, a first conductive line is formed in a dielectric layer. At block 1204, a conductive pillar is formed over the first conductive line. At block 1206, a liner is formed in a trench adjacent to the first conductive line. In some embodiments of the invention, a portion of the liner extends over the conductive pillar.

At block 1208, a lower metal line and a top via are subtractively formed on the liner in the trench. In some embodiments of the invention, a bottommost surface of the first conductive line is not coplanar to a bottommost surface of the lower metal line. In some embodiments of the invention, the bottommost surface of the first conductive line is lower than the bottommost surface of the lower metal line. In some embodiments of the invention, the bottommost surface of the first conductive line is higher than the bottommost surface of the lower metal line.

In some embodiments of the invention, subtractively forming the lower metal line and the top via includes depositing a bulk conductive material over the liner, planarizing the bulk conductive material, and removing portions of the bulk conductive material to define the lower metal line and the top via. In other words, the lower metal line and the top via can be monolithically formed from a common conductive material.

In some embodiments of the invention, a capping layer is formed on sidewalls of the top via and a top surface of the lower metal line. In some embodiments of the invention, the first conductive line and the lower metal line comprise different materials.

In some embodiments of the invention, a second conductive line is formed on the top via and a third conductive line is formed on the conductive pillar. In some embodiments of the invention, a first inter-layer dielectric separation distance between the lower metal line and the second conductive line is different than a second inter-layer dielectric separation distance between the first conductive line and the third conductive line. In some embodiments of the invention, the first inter-layer dielectric separation distance is lower than the second inter-layer dielectric separation distance. In some embodiments of the invention, the first inter-layer dielectric separation distance is greater than the second inter-layer dielectric separation distance.

In some embodiments of the invention, a bottommost surface of the second conductive line is higher than a bottommost surface of the third conductive line.

In some embodiments of the invention, a conductive plug is formed between the first conductive line and the conductive pillar. In some embodiments of the invention, a bottommost surface of the second conductive line is coplanar to a bottommost surface of the third conductive line.

The methods and resulting structures described herein can be used in the fabrication of IC chips. The resulting IC chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes IC chips, ranging from toys and other low-end applications to advanced computer products having a display, a keyboard or other input device, and a central processor.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Similarly, the term “coupled” and variations thereof describes having a communications path between two elements and does not imply a direct connection between the elements with no intervening elements/connections between them. All of these variations are considered a part of the specification. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, are used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (e.g., rotated 90 degrees or at other orientations), and the spatially relative descriptors used herein should be interpreted accordingly.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The phrase “selective to,” such as, for example, “a first element selective to a second element,” means that the first element can be etched and the second element can act as an etch stop.

The term “conformal” (e.g., a conformal layer or a conformal deposition) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a <100> orientated crystalline surface can take on a <100> orientation. In some embodiments of the invention of the invention, epitaxial growth and/or deposition processes can be selective to forming on semiconductor surface, and may or may not deposit material on other exposed surfaces, such as silicon dioxide or silicon nitride surfaces.

As used herein, “p-type” refers to the addition of impurities to an intrinsic semiconductor that creates deficiencies of valence electrons. In a silicon-containing substrate, examples of p-type dopants, i.e., impurities, include but are not limited to, boron, aluminum, gallium, and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), chemical-mechanical planarization (CMP), and the like. Reactive ion etching (ME), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method for forming a semiconductor device, the method comprising:
forming a first conductive line in a dielectric layer;
forming a conductive pillar over the first conductive line;
forming a liner in a trench adjacent to the first conductive line, wherein a portion of the liner extends over the conductive pillar; and
subtractively forming a lower metal line and a top via on the liner in the trench.

2. The method of claim 1 further comprising forming a capping layer on sidewalls of the top via and a top surface of the lower metal line.

3. The method of claim 1 further comprising:
forming a second conductive line on the top via; and
forming a third conductive line on the conductive pillar.

4. The method of claim 3, wherein a first dielectric separation distance between the lower metal line and the second conductive line is different than a second dielectric separation distance between the first conductive line and the third conductive line.

5. The method of claim 4, wherein the first dielectric separation distance is lower than the second dielectric separation distance.

6. The method of claim 4, wherein the first dielectric separation distance is greater than the second dielectric separation distance.

7. The method of claim 3, wherein a bottommost surface of the first conductive line is not coplanar to a bottommost surface of the lower metal line.

8. The method of claim 7, wherein the bottommost surface of the first conductive line is lower than the bottommost surface of the lower metal line.

9. The method of claim 7, wherein the bottommost surface of the first conductive line is higher than the bottommost surface of the lower metal line.

10. The method of claim 3, wherein a bottommost surface of the second conductive line is higher than a bottommost surface of the third conductive line.

11. The method of claim 3 further comprising forming a conductive plug between the first conductive line and the conductive pillar.

12. The method of claim 11, wherein a bottommost surface of the second conductive line is coplanar to a bottommost surface of the third conductive line.

13. The method of claim 1, wherein subtractively forming the lower metal line and the top via comprises:
depositing a bulk conductive material over the liner;
planarizing the bulk conductive material; and
removing portions of the bulk conductive material to define the lower metal line and the top via.

14. The method of claim 1, wherein the first conductive line and the lower metal line comprise different materials.

15. A semiconductor device comprising:
a first conductive line in a dielectric layer;
a conductive pillar over the first conductive line;
a lower metal line adjacent to the first conductive line;
a top via on the lower metal line;
a second conductive line on the top via; and
a third conductive line on the conductive pillar;
wherein a first dielectric separation distance between the lower metal line and the second conductive line is different than a second dielectric separation distance between the first conductive line and the third conductive line.

16. The semiconductor device of claim 15 further comprising a capping layer on sidewalls of the top via and a top surface of the lower metal line.

17. The semiconductor device of claim 15, wherein a bottommost surface of the first conductive line is not coplanar to a bottommost surface of the lower metal line.

18. The semiconductor device of claim 15, wherein a bottommost surface of the second conductive line is higher than a bottommost surface of the third conductive line.

19. The semiconductor device of claim 15 further comprising a conductive plug between the first conductive line and the conductive pillar.

20. The semiconductor device of claim 19, wherein a bottommost surface of the second conductive line is coplanar to a bottommost surface of the third conductive line.
